(19) United States
(12) Patent Application Publication
(10) Pub. No.: US 2025/0338532 A1
(43) Pub. Date: Oct. 30, 2025

(54) LDMOS NANOSHEET TRANSISTOR INCLUDING A NANOSHEET DRIFT REGION FIELD PLATE

(71) Applicant: Texas Instruments Incorporated, Dallas, TX (US)

(72) Inventors: Henry Litzmann Edwards, Garland, TX (US); Ali Saadat, Santa Clara, CA (US)

(21) Appl. No.: 18/651,334

(22) Filed: Apr. 30, 2024

(51) Int. Cl. H01L 29/775; H01L 29/06; H01L 29/08; H01L 29/40; H01L 29/423; H01L 29/66; H01L 29/78; H01L 29/786

(52) U.S. Cl. CPC H10D 30/43; H10D 30/014; H10D 30/0281; H10D 30/65; H10D 30/6735; H10D 30/6757; H10D 62/121; H10D 62/154; H10D 62/158; H10D 64/017; H10D 64/018; H10D 64/117

(57) ABSTRACT

An integrated circuit includes a nanosheet laterally-diffused metal oxide semiconductor (LDMOS) transistor. The transistor includes source and drain regions having a first conductivity type that extend into a semiconductor substrate. A nanosheet region including semiconducting nanosheets extends between the source region and the drain region. The nanosheets alternate with gate conductor layers that extend between the source region and the drain region. The nanosheets also alternate with field plate conductor layers that extend between the gate conductor layers and the drain region.

### TECHNICAL FIELD

This disclosure relates to the field of microelectronic devices. More particularly, but not exclusively, this disclosure relates to gated devices such as LDMOS transistors and in particular nanosheet LDMOS transistors.

### BACKGROUND

Semiconductor components are being continually improved to reliably operate with smaller feature sizes. Fabricating semiconductor devices that have increasingly higher performance while meeting performance and reliability specifications presents diverse challenges.

### SUMMARY

This summary is provided to introduce a brief overview of disclosed concepts in a simplified form that are further described below in the detailed description including the drawings provided. This summary is not intended to limit the scope of the disclosure or the claims.

Disclosed examples include microelectronic devices, e.g. Integrated circuits and methods of making such devices. One example includes a microelectronic device including a nanosheet laterally-diffused metal oxide semiconductor (LDMOS) transistor. The transistor includes source and drain regions having a first conductivity type that extend into a semiconductor substrate. A nanosheet region including semiconducting nanosheets extends between the source region and the drain region. The nanosheets alternate with gate conductor layers that extend between the source region and the drain region. The nanosheets also alternate with field plate conductor layers that extend between the gate conductor layers and the drain region.

### BRIEF DESCRIPTION OF THE VIEWS OF THE DRAWINGS

FIG. 1AA is a top view and FIG. 1AB through FIG. 1BJ are cross sections of an example microelectronic device including a nanosheet LDMOS transistor with a field plate in various stages of formation.

FIG. 2A is a top-down view of an example microelectronic device including a nanosheet LDMOS transistor including multiple field plates after formation.

FIG. 2B is a cross section of an example microelectronic device including a nanosheet LDMOS transistor including multiple field plates after formation.

FIG. 3A is a top-down view of an example microelectronic device including a multi-finger nanosheet LDMOS transistor with a field plate after formation.

FIG. 3B and FIG. 3C are cross sections of an example microelectronic device including a multi-finger nanosheet LDMOS transistor with a field plate after formation.

FIG. 4A is a top-down view of an example microelectronic device including a nanosheet LDMOS transistor including a field plate and multiple nanosheet dielectric spacers after formation.

FIG. 4B is a cross section of an example microelectronic device including a nanosheet LDMOS transistor including a field plate and multiple dielectric spacers after formation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events unless otherwise stated. Furthermore, some of the illustrated acts or events may be omitted in some examples in accordance with the present disclosure.

In addition, although some of the examples illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present disclosure may be illustrated by examples directed to active devices, it is not intended that these illustrations be a limitation on the scope or applicability of the present disclosure. It is not intended that the active devices of the present disclosure be limited to the physical structures illustrated. These structures are included to demonstrate the utility and application of the present disclosure to various examples.

It is noted that terms such as top, bottom, over, above, and under may be used in this disclosure. These terms should not be construed as limiting the position or orientation of a structure or element, but should be used to provide spatial relationship between structures or elements. The terms “lateral” and “laterally” refer to directions parallel to a plane corresponding to a surface of a layer, for example a top surface of a semiconductor substrate. Moreover, the term “approximately,” as used herein, may refer to ±5% to ±10% variations of the recited values in some cases. In other cases, the term “approximately” may refer to ±10% to ±20% variations of the recited values.

Microelectronic devices are being continually improved to reliably operate with higher performance and smaller feature sizes. Fabricating such microelectronic devices satisfying area scaling and reliability specifications presents ongoing challenges. Some gate-controlled devices such as metal-oxide-semiconductor (MOS) transistors include features for supporting high voltage operations, e.g. with a voltage applied to their drain (or drain structure) of 20 V, 30 V, 40 V, or even greater. Such MOS transistors may include drain diffusion profiles (or drain junction profiles) devised to support the high voltages applied to the drain, e.g. Having an extended portion to distribute the voltage drop across greater distances. Accordingly, such MOS transistors may be referred to as extended drain (ED) MOS transistors, for example drain-extended n-channel MOS (DENMOS) transistors, drain-extended p-channel MOS (DEPMOS) transistors, laterally-diffused MOS (LDMOS) transistors, as well as groups of DENMOS and DEPMOS transistors (which may be referred to as complimentary drain-extended MOS or DECMOS transistors). Other gate controlled microelectronic devices may include a gated bipolar semiconductor device, a gated unipolar semiconductor device, an insulated gate bipolar transistor (IGBT), a metal oxide semiconductor-triggered SCR, a MOS-controlled thyristor, and a gated diode. ED transistors are scaled down to smaller sizes to reduce microchip cost and improve circuit performance by reducing parasitic resistance and capacitance. It can be challenging to maintain good reliability and yield, so it may be advantageous to improve transistor performance independently of lateral lithographic scaling.

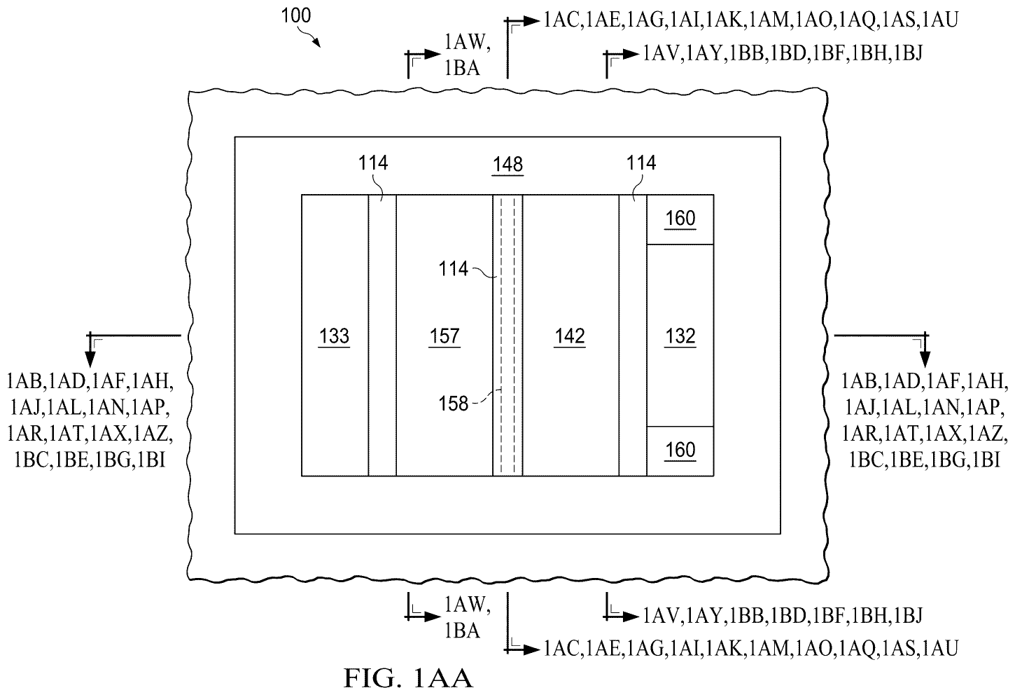

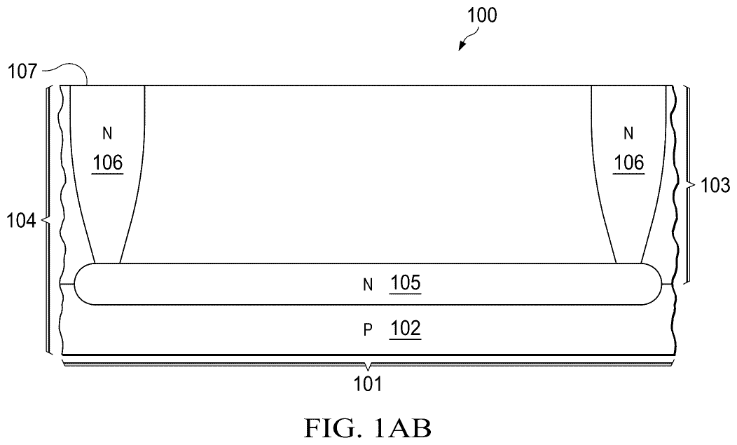

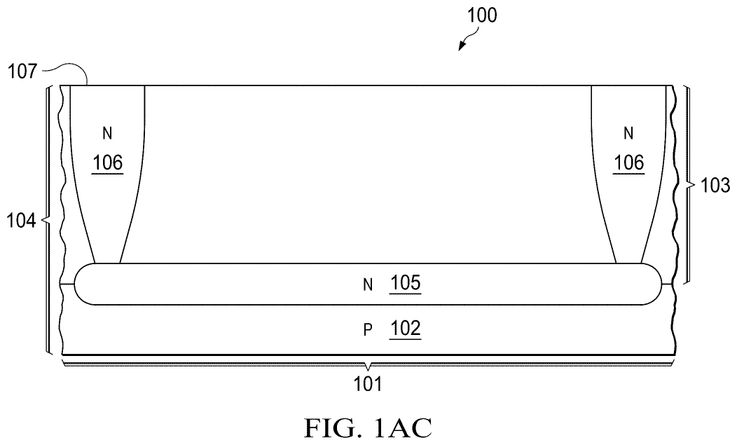

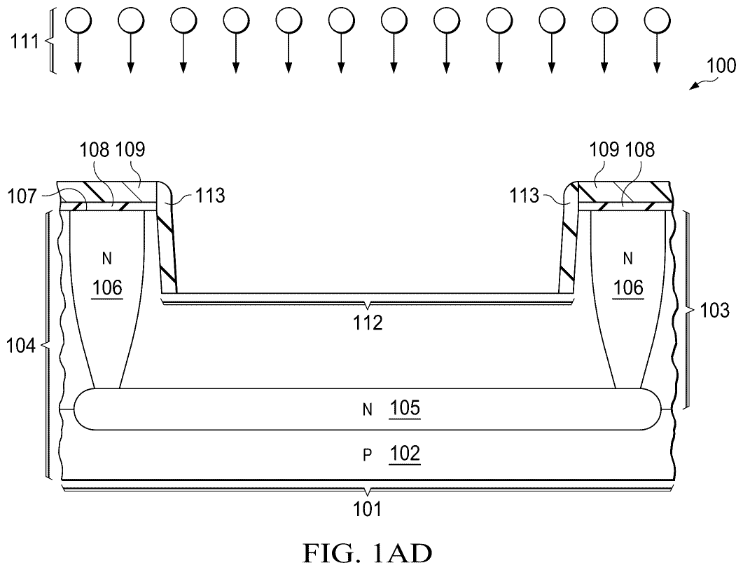

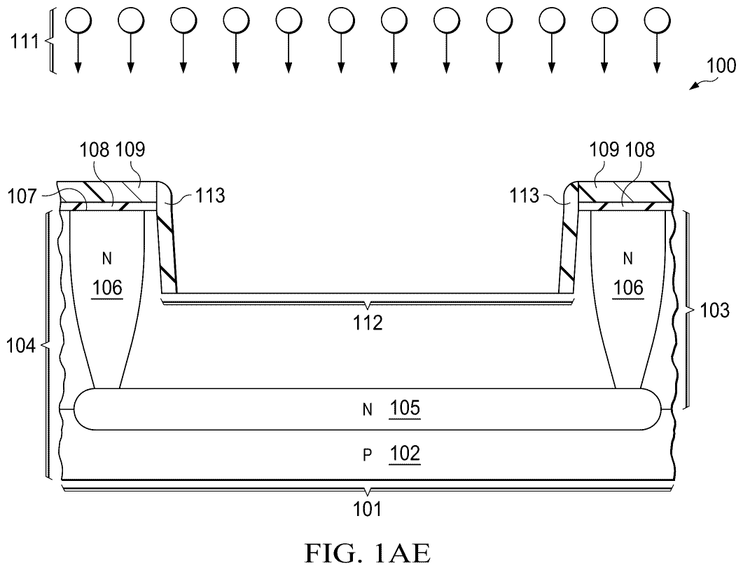

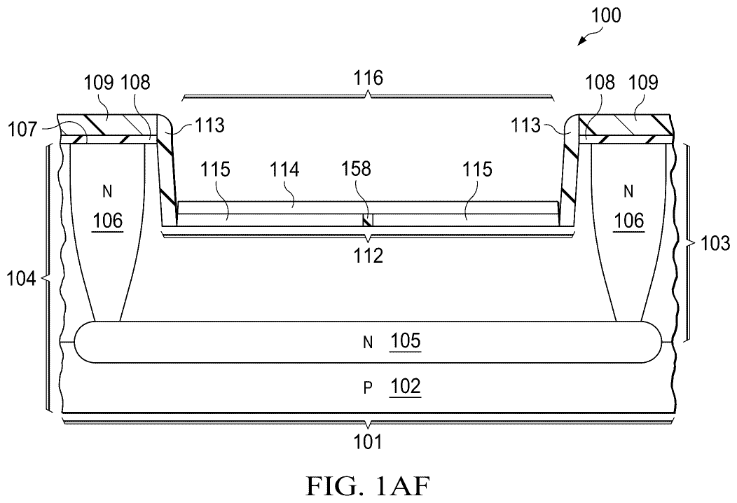

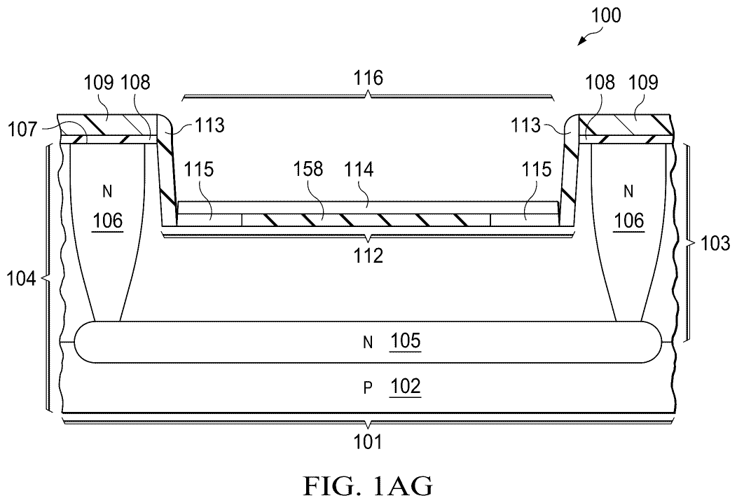

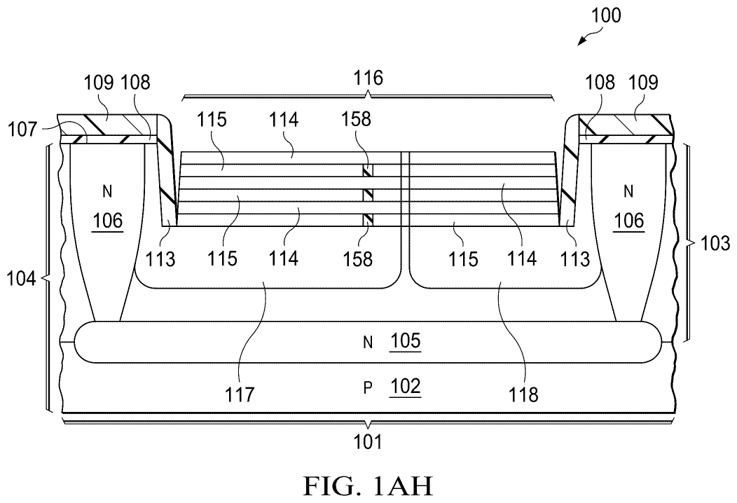

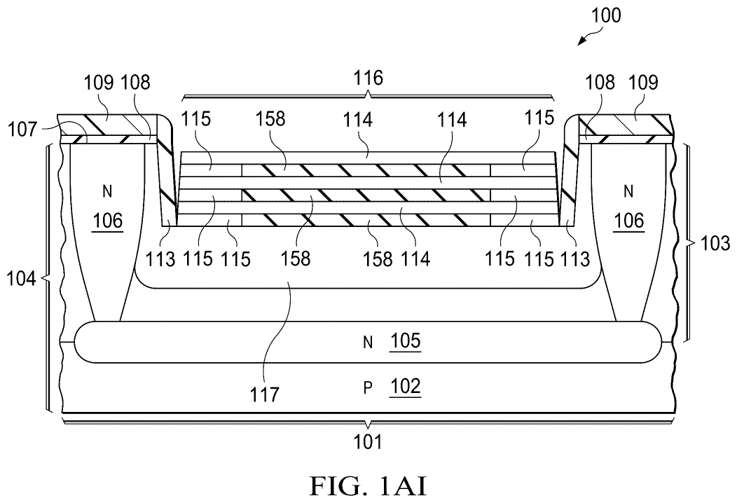

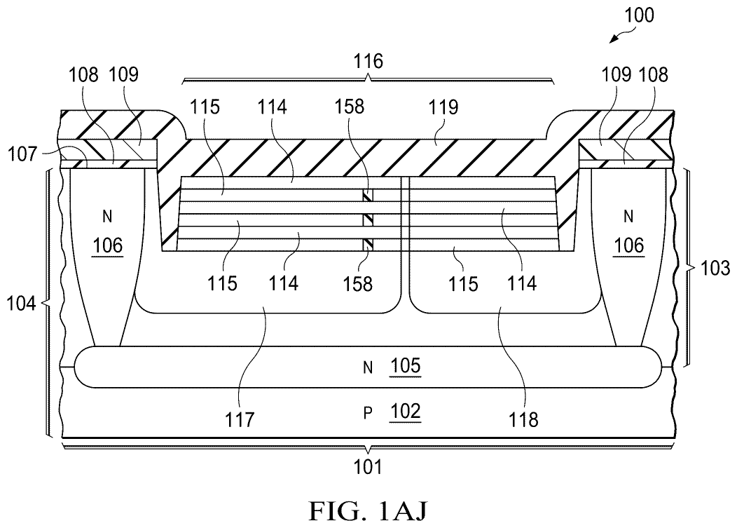

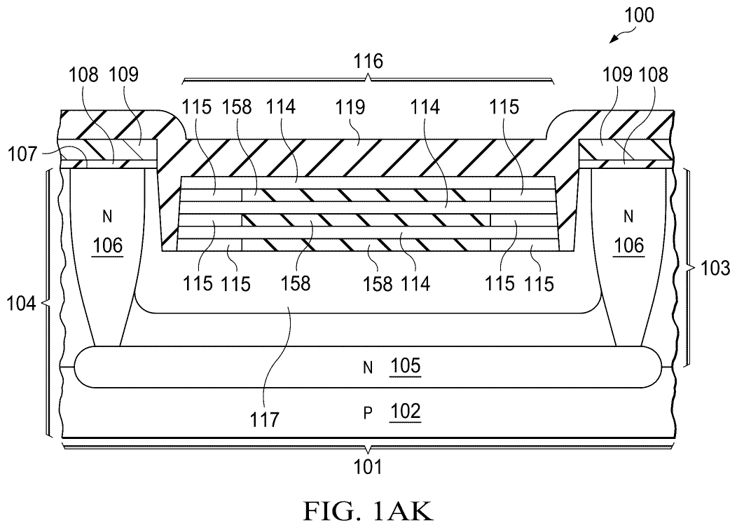

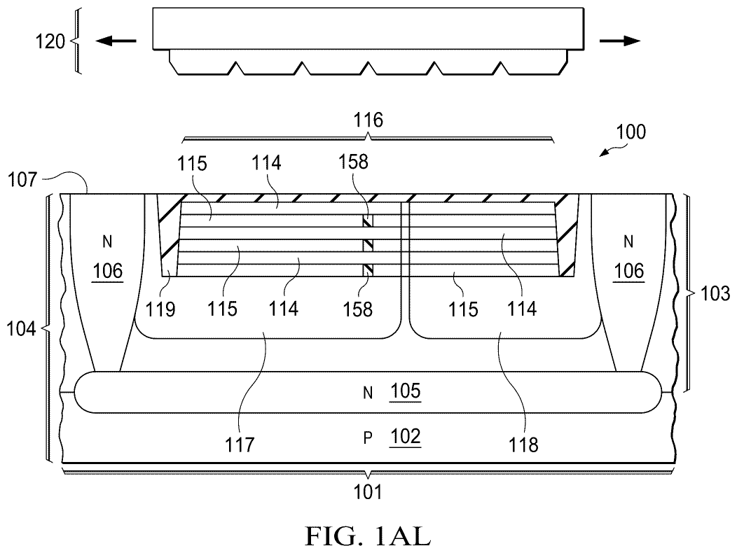

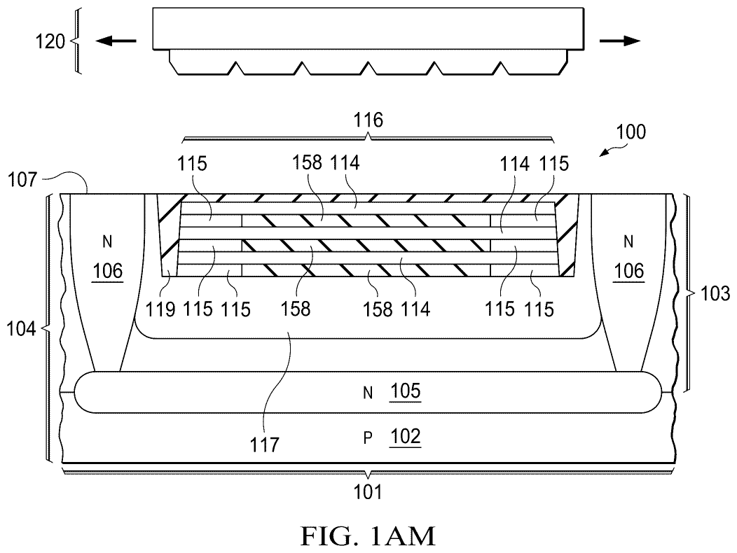

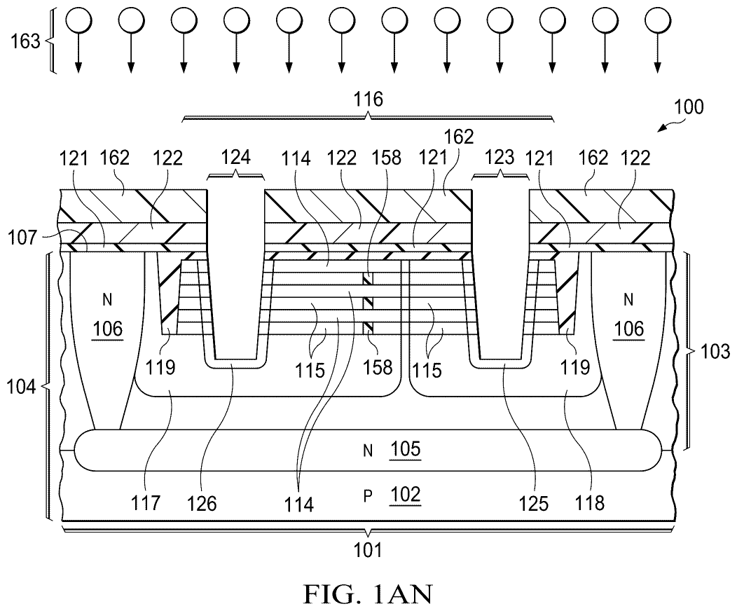

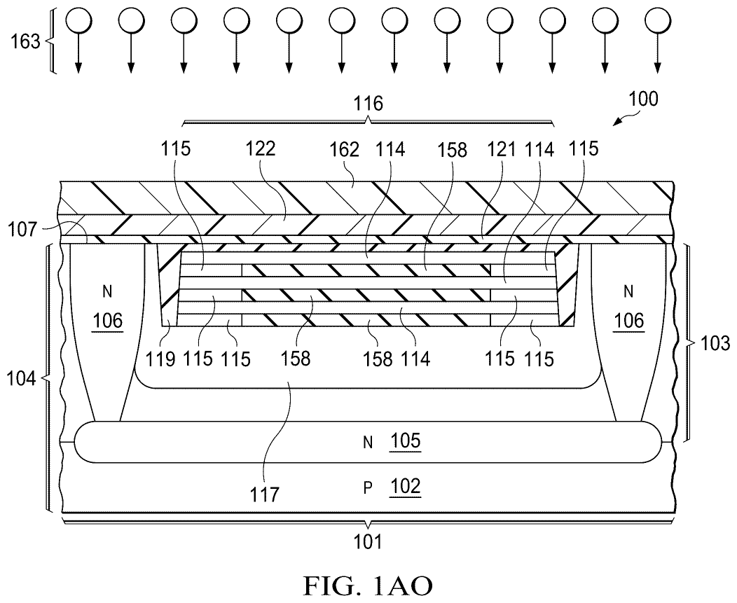

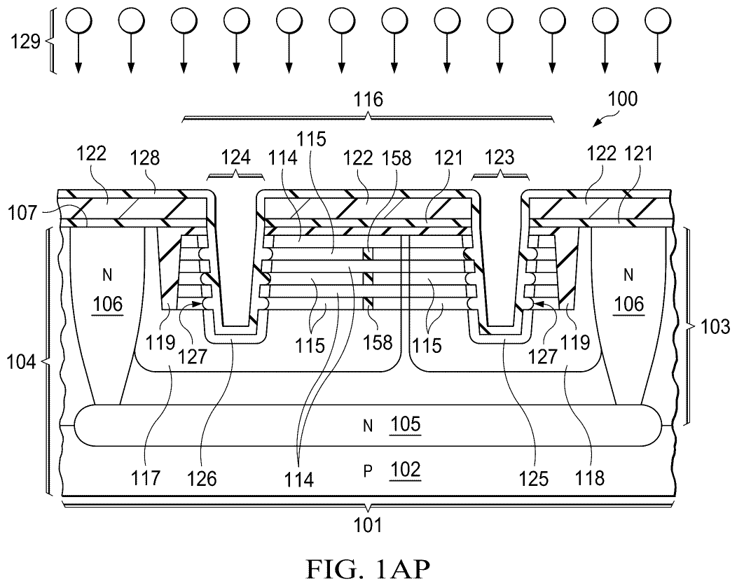

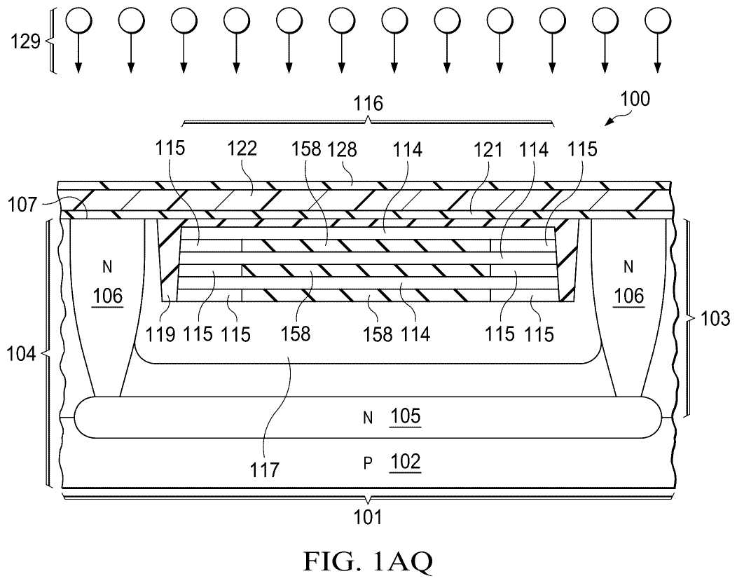

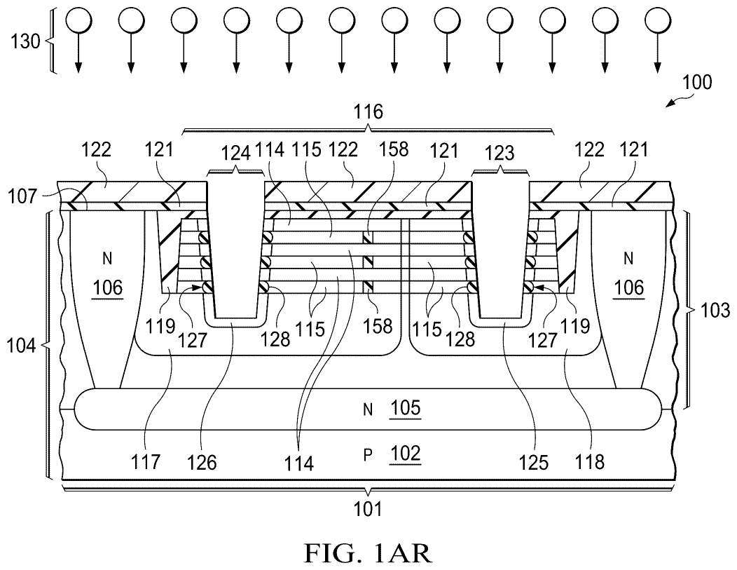

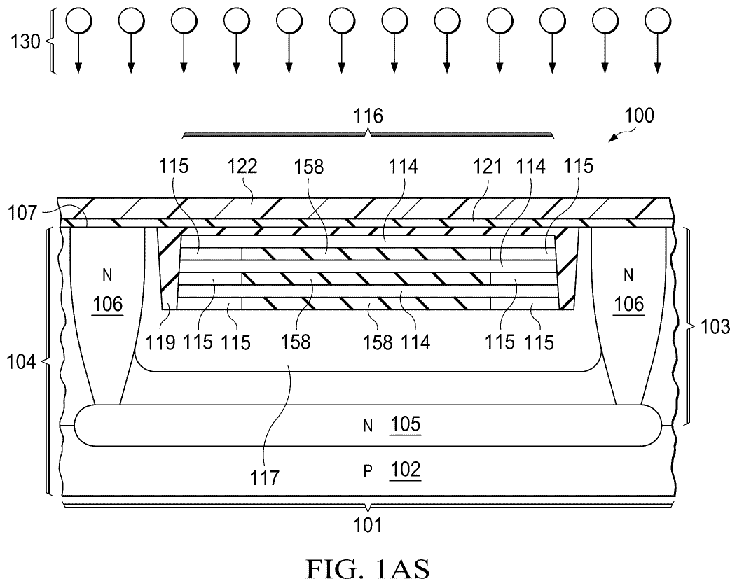

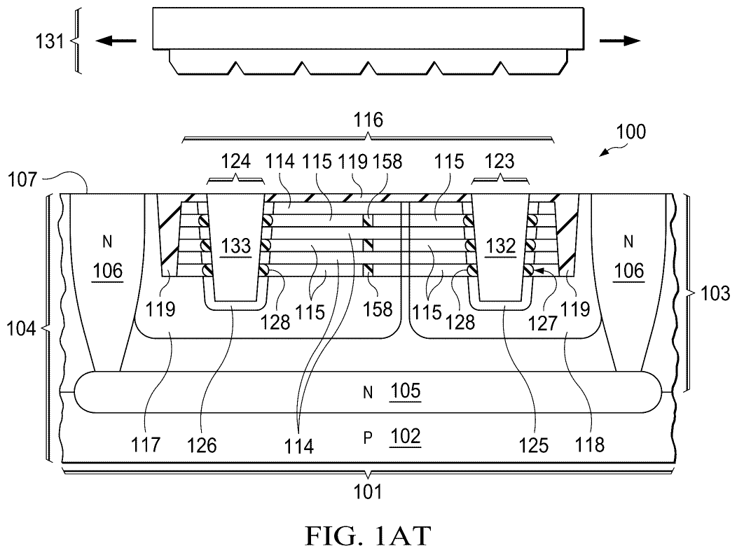

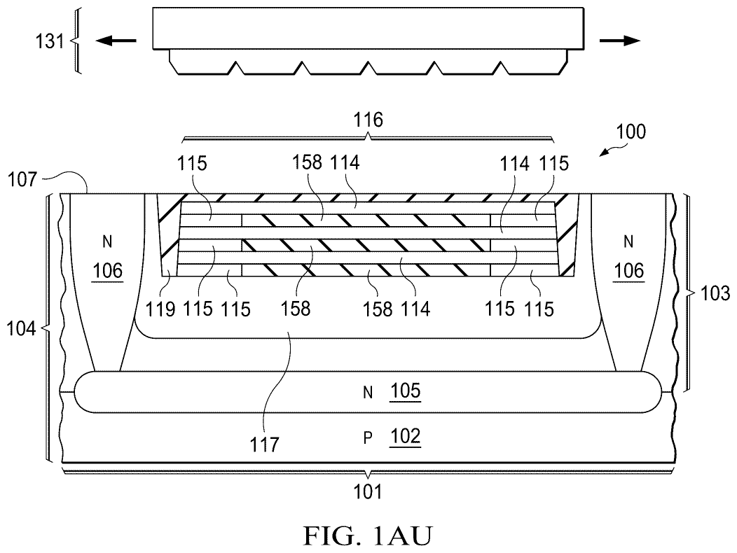

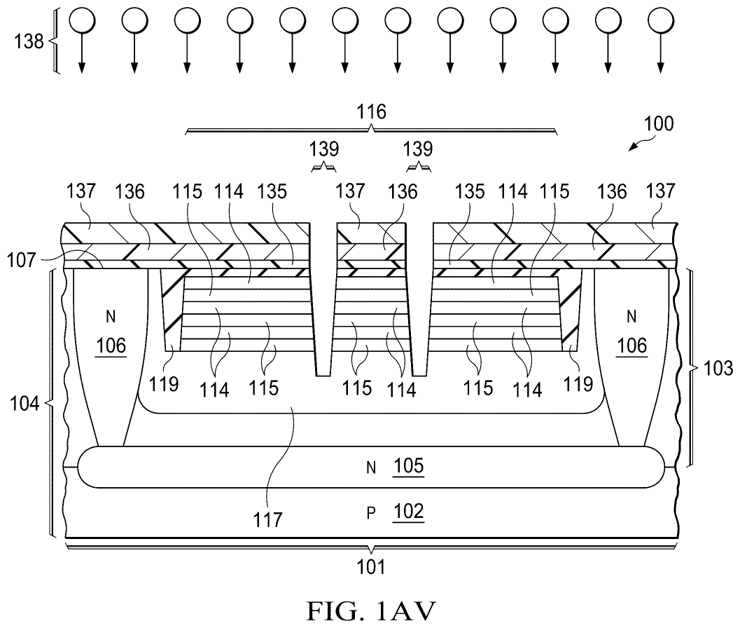

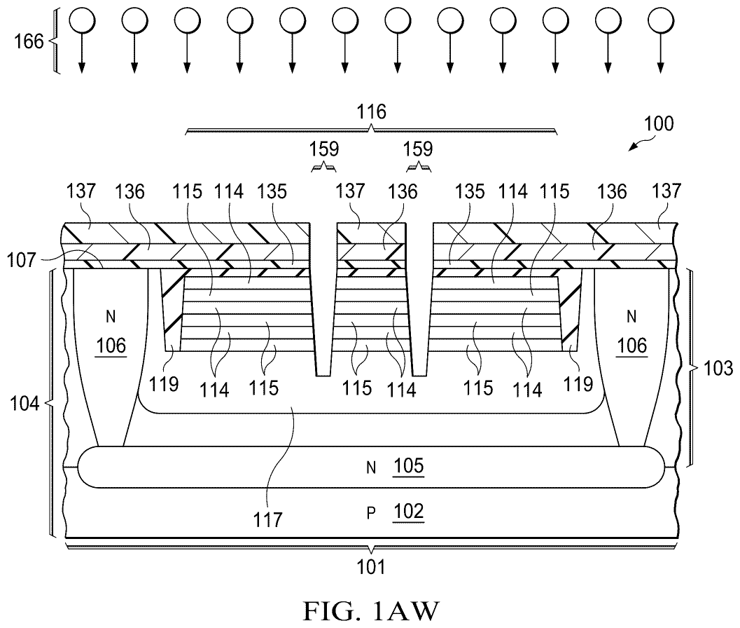

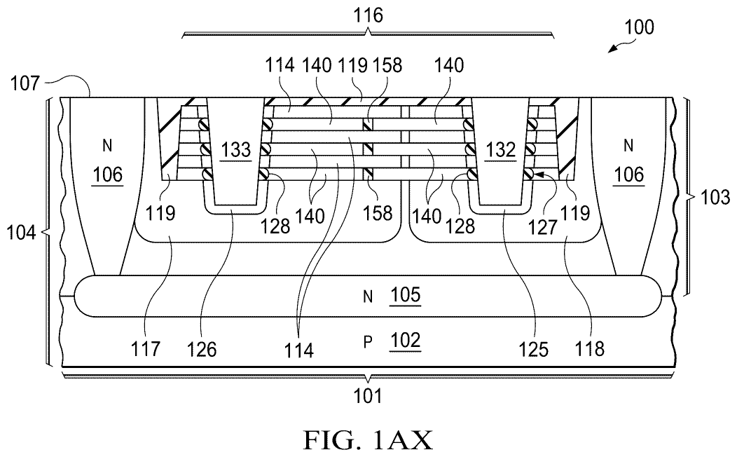

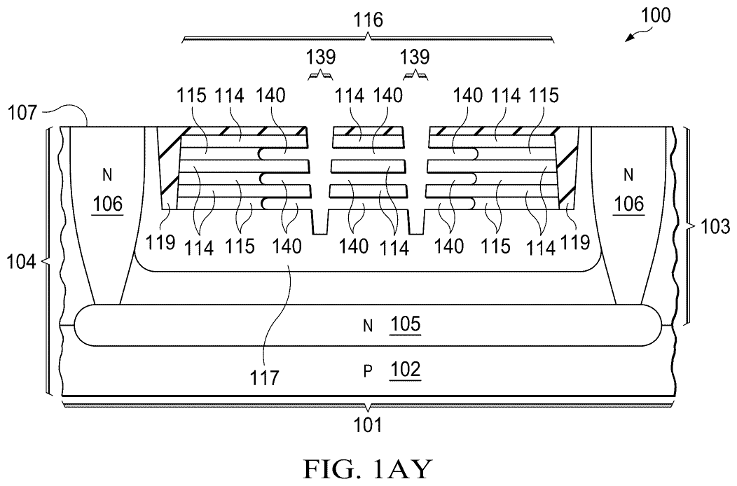

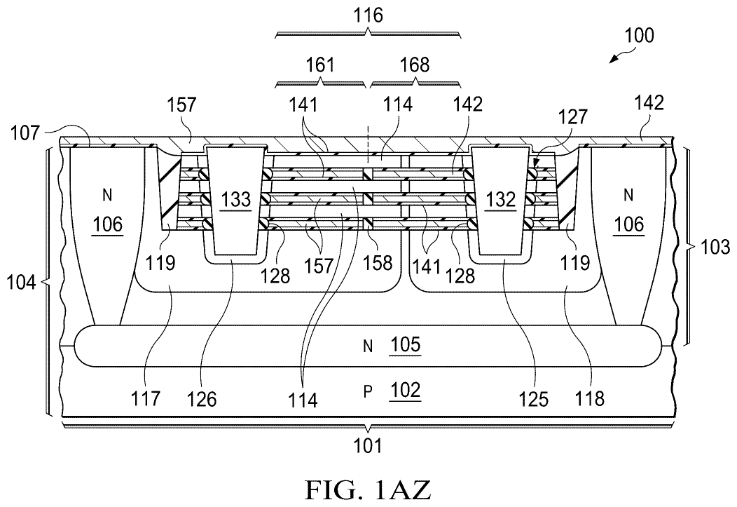

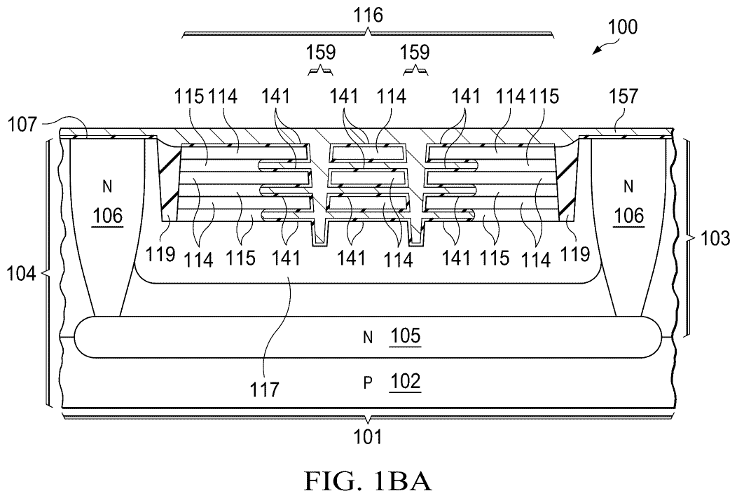

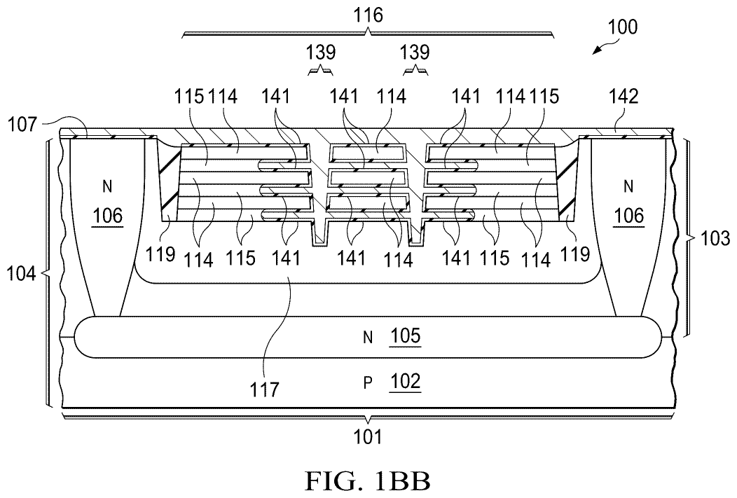

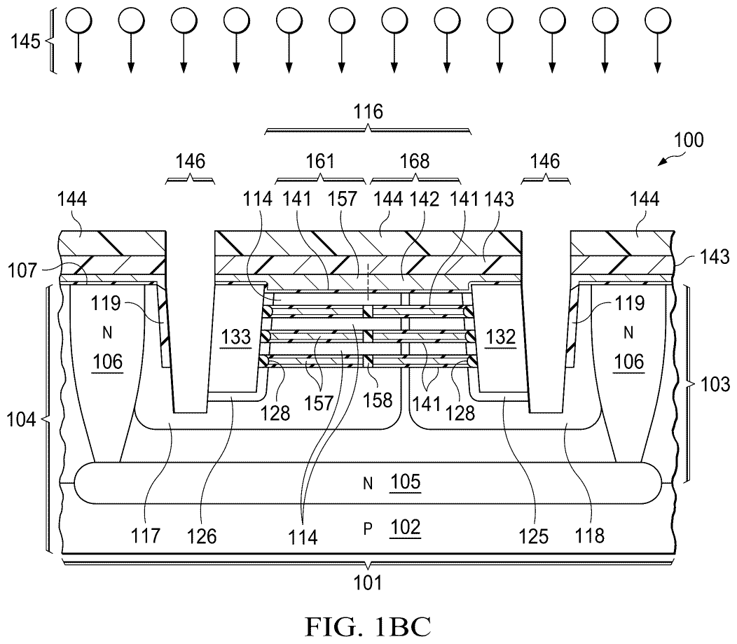

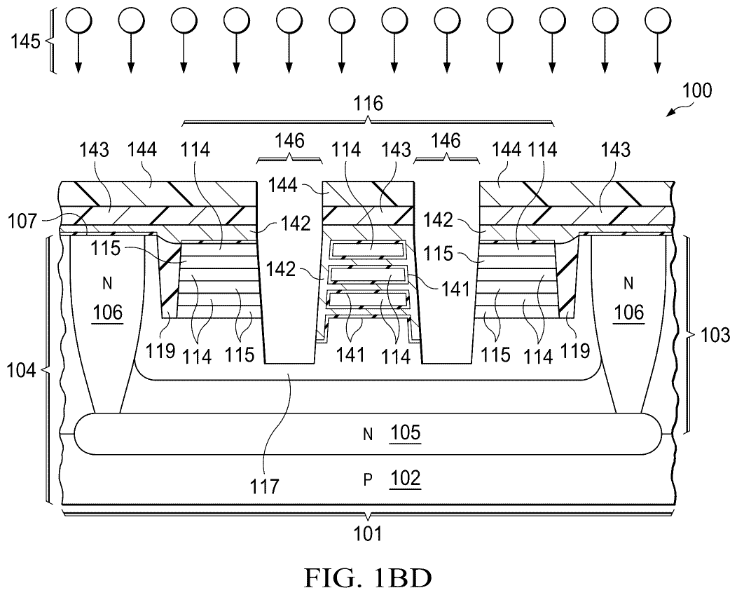

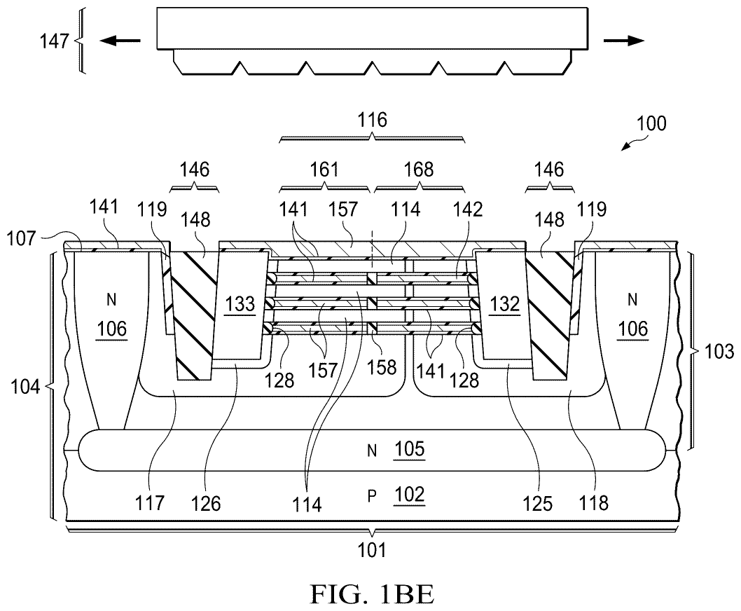

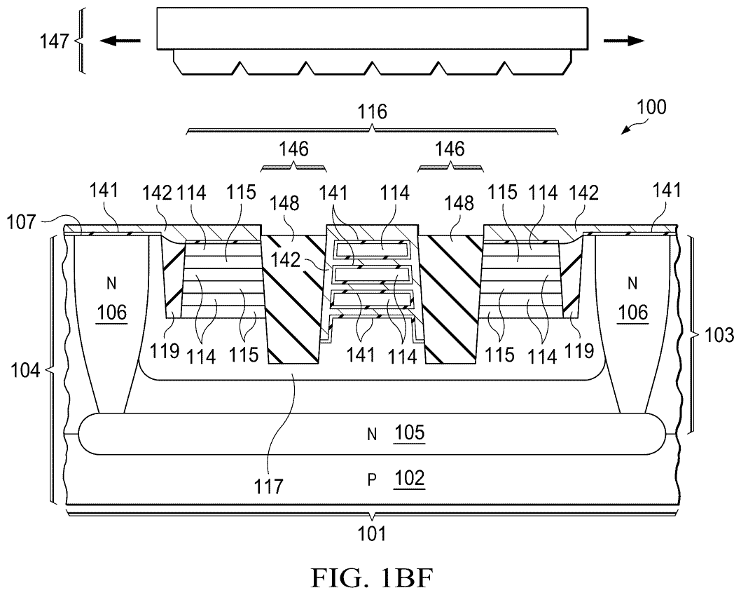

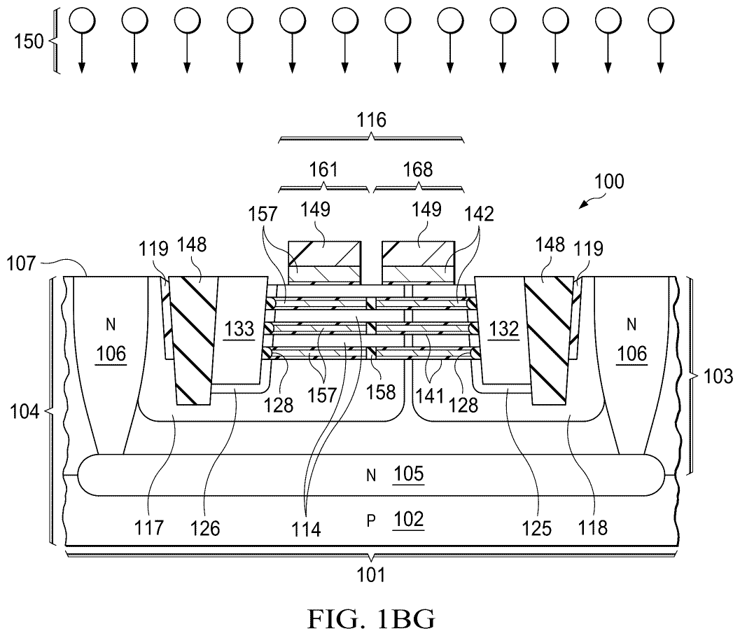

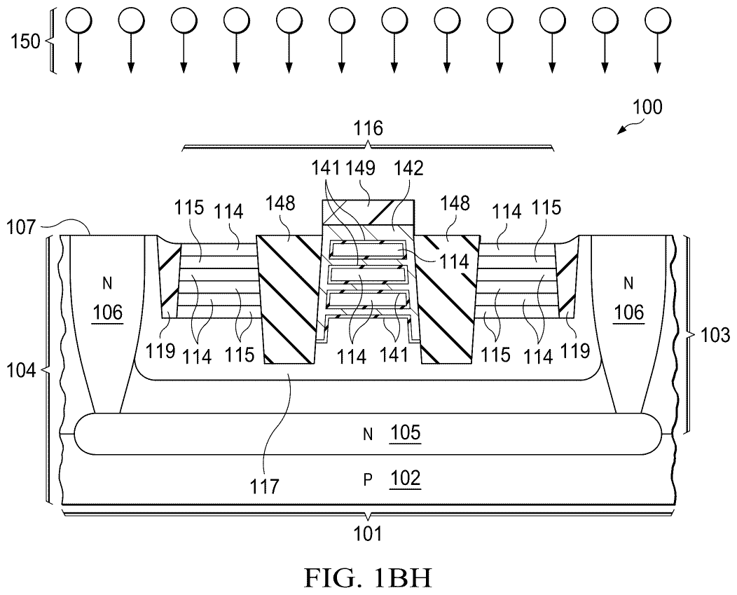

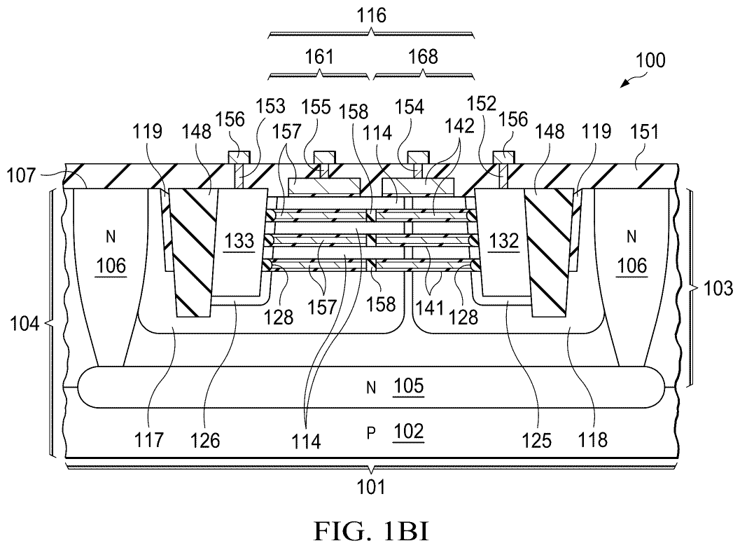

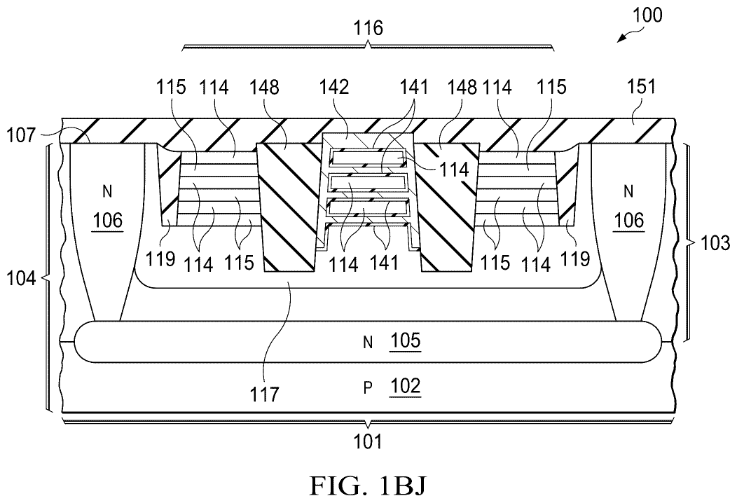

Stacking multiple transistor channels may be advantageous by reducing on-resistance and increasing on-current proportionally to the number of layers stacked. An example ED transistor as described in FIG. 1AA-1BJ may have a nanosheet region doping profile whose dose lies in the resurf range 10¹²-10¹³ cm⁻², which sets the drain drift region contribution to source-drain on resistance (RDSON), which often is the dominant contribution. Therefore, stacking multiple nanosheet ED transistors in parallel enables the reduction of RDSON in a given area, so that the cost figure of merit specific on resistance (RSP) which is equal to the RDSON times the area is reduced and power technology scaling can be improved for a given lithographic scaling capability. The physical geometry of the nanosheets for ED transistors differs from those in nanosheet digital CMOS transistors. In general, nanosheet digital CMOS transistors use nanosheet architecture including nanosheet layers just a few nanometers thick. For high voltage ED transistors, however, drain drift region mobility may be beneficial, and nanosheets thicker than 10 nm, such as in the range from 20 nm to 500 nm or greater, may be used to achieve target RSP values for efficient power circuit design. In some examples, the nanosheet thickness could be 50 nm to 500 nm, or 100 nm to 300 nm, which may keep the drain drift region doping concentration low enough to preserve high electron mobility, hence low RSP.

Some aspects of nanoribbon transistors are described in U.S. patent application Ser. No. 18/525,638, which is incorporated herein by reference in its entirety. The present disclosure describes similar devices including one or more field plates. The addition such field plates to an ED transistor such as the example device as described in FIG. 1AA through FIG. 1BJ may improve the electric field uniformity along the drain drift region. One or more field plates enables better electrostatic control in the drift region avoiding localized high-field areas. In other words, field plates spread equipotential lines through the drain drift region and reduce non-uniformity of equipotential line spacing. One way to do this is by placing one or more field plates along the drain drift region whose voltage varies monotonically from the source region and the gate region to the drain. External circuitry such as a resistor string or a string of breakdown diodes such as Zener diodes or avalanche diodes may be used to enforce this monotonic field plate voltage increase from the source region and the gate region (which are both grounded in the off-state) to the drain region. In the on-state, the field plates may be biased to accumulate drift region carriers to reduce the drain region to source region resistance. Enhanced drift accumulations, or smaller drain region to source region resistance, can be achieved in the on-state by either larger field plates or higher field plate potential. Optimization with respect to field plate size, field plate spacing, number of field plates and field plate potential may enhance the device performance in the off state as well as in the on-state.

The disclosure includes several examples of microelectronic devices including a nanosheet LDMOS transistor incorporating one or more field plates. While such examples and variations may be expected to provide lower RDSON than some baseline devices of similar size and otherwise similar performance characteristics, no particular result is a requirement of the present disclosure unless explicitly recited in a particular claim. As used herein the term “superlattice” means a periodic structure of layers of at least two different materials. A superlattice may have many such layers, and in some cases may have as few as two layers including a layer of a first material and a layer of a second material. As used herein the term “nanosheet” means a layer within a superlattice and having a thickness (in a direction normal to the major surface of a substrate over which the superlattice is formed) no greater than 500 nm. A nanosheet may also be an active layer of a semiconductor device including the nanosheet. As used herein, the term “sacrificial layer” means a layer initially formed in the superlattice, of which all or a portion of which is removed later in the formation of the nanosheet transistor.

FIG. 1AA through FIG. 1BJ show in successive stages of formation, a first type of microelectronic device to which the principles of the disclosure may be beneficially applied. FIG. 1AA through FIG. 1BJ show a top-down view and cross-sectional views of an example microelectronic device 100, e.g. Including a nanosheet LDMOS transistor 101, herein referred to as a nanosheet transistor 101. The nanosheet transistor 101 includes a gate conductor region 168 and a field plate region 161 which are electrically isolated from each other by a nanosheet dielectric spacer 158. (See, e.g. FIG. 1AZ.) Without implied limitation, a nanosheet region 116 in this example includes semiconductor layers 114 herein sometimes referred to as nanosheet layers 114 and described below that are implemented in an n-type laterally diffused metal oxide semiconductor (n-type LDMOS) nanoshect transistor 101. A p-type nanosheet LDMOS transistor that includes the nanosheet region 116 is within the scope of this disclosure. In the example nanosheet transistor 101, dopants of a first conductivity type are n-type dopants and dopants of a second conductivity type are p-type dopants. Examples are described herein with silicon as the semiconductor material for the nanosheet layer 114 and SiGe as the sacrificial layers 115 which is initially present between the nanosheet layers 114. Other examples within the scope of the disclosure may use other combinations of nanosheet layers 114 and sacrificial layers 115. For example, the roles of silicon and SiGe may be reversed such that SiGe is used as the semiconductor material of the nanosheet layers 114 and silicon is used as the sacrificial layers 115. Other combinations may also be used, where the materials may be formed in the alternating layers, and one layer may be preferentially removed leaving intact nanosheet layers 114.

FIG. 1AA shows a top-down representation of the microelectronic device 100 including the nanoshect transistor 101 after formation. The top-down view shows a shallow trench isolation (STI) region 148 surrounds the nanosheet transistor 101. Nanosheet layers 114 are between a source region 132 and a drain region 133. A p-type back gate region 160 is conductively connected to the source region 132. For clarity, at successive stages of formation where figures are provided, figures may show a cross section along the axis through the source region 132, or perpendicular to the axis between the source region 132 and the drain region 133 a first conductive layer 142 hereinafter referred to as a gate conductor 142, a second conductive layer 157 hereinafter referred to as a field plate conductor 157, and the nanosheet dielectric spacer 158.

Referring to FIG. 1AB and FIG. 1AC, the microelectronic device 100 including the nanosheet transistor 101 is formed in and on a base wafer 102, such as a silicon wafer. The base wafer 102 may have a second conductivity type, which may be p-type in this example, as indicated in FIG. 1AB and FIG. 1AC. In an alternate version of this example, the base wafer 102 may include a dielectric material, such as silicon dioxide or sapphire, to provide a silicon-on-insulator substrate. A semiconductor material 103 is formed on the base wafer 102. The semiconductor material 103 includes primarily silicon, and may consist essentially of silicon and dopants, such as boron, and may have the second conductivity type, that is, p-type. The semiconductor material 103 may be formed by an epitaxial process and may be 5 μm to 15 μm by way of example. The semiconductor material 103 extends to a top surface 107. The base wafer 102 and the semiconductor material 103 form the substrate 104.

A buried layer 105 may be formed in the substrate 104, extending into both the base wafer 102 and the semiconductor material 103. The buried layer 105 has a first conductivity type, opposite from the second conductivity type. In this example, the first conductivity type is n-type. The buried layer 105 may be formed by implanting dopants of the first conductivity type, such as phosphorus, arsenic, or antimony, into the base wafer 102 before the semiconductor material 103 is formed. The base wafer 102 may be annealed prior to forming the semiconductor material 103, and the semiconductor material 103 may subsequently be formed by an epitaxial process of thermal decomposition of silane, during which the dopants of the first conductivity type diffuse deeper into the base wafer 102 and into the semiconductor material 103, forming the buried layer 105.

A deep well 106 may be formed in the semiconductor material 103, extending from the top surface 107 of the substrate 104 to the buried layer 105. The deep well 106 may have the first conductivity type, n-type in this example. The deep well 106 may be formed by implanting dopants of the first conductivity type, such as phosphorus, into the semiconductor material 103, followed by a thermal drive to diffuse the implanted dopants to the buried layer 105 and activate the implanted dopants. The deep well 106 may have an average concentration of the dopants of the first conductivity type that is at least 2 to 10 times greater than an average concentration of dopants of the second conductivity type in the semiconductor material 103 outside of the deep well 106. The deep well 106 provides isolation between the nanosheet transistor 101 and other components of the microelectronic device 100. The deep well 106 may preferably be degenerately doped to provide low leakage between the nanosheet transistor 101 and other components of the microelectronic device 100.

Referring to FIG. 1AD and FIG. 1AE, cross sections are shown after a nanosheet superlattice trench 112 has been formed. After formation of the buried layer 105 and the deep well 106, first pad oxide layer 108 may be formed on the top surface 107 of the substrate 104. The first pad oxide layer 108 may include primarily silicon dioxide, may be formed by a thermal oxidation process or a thermal chemical vapor deposition (CVD) process, and may have a thickness of 5 nm to 200 nm, by way of example. A first hard mask layer 109 may be formed on the first pad oxide layer 108. The first hard mask layer 109 may include a layer of a material composed primarily of silicon nitride, and a layer of a material containing primarily silicon dioxide. The first hard mask layer 109 may have a thickness of 50 nm to 3 μm, depending on a depth of nanosheet superlattice trench 112. The first pad oxide layer 108 may provide stress relief between the semiconductor material 103 and the first hard mask layer 109. The silicon nitride portion of the first hard mask layer 109 may provide a stop layer for subsequent etch and planarization processes. The silicon dioxide layer of the first hard mask layer 109 may provide a hard mask during a superlattice trench etch 111 to form the nanosheet superlattice trench 112. A superlattice trench photomask (not specifically shown) may be formed on the first hard mask layer 109 with openings which exposes the first hard mask layer 109 in areas for the nanosheet superlattice trench 112.

A superlattice trench etch 111 forms the nanosheet superlattice trench 112 in the substrate 104. The superlattice trench etch 111 may include multiple steps. After the superlattice trench etch 111, the superlattice trench photomask is removed. A superlattice trench dielectric sidewall 113 is formed after the superlattice trench photomask is removed. The superlattice trench dielectric sidewall 113 is formed by depositing a blanket layer of a dielectric such as silicon dioxide or silicon nitride followed by an anisotropic etch (neither process specifically shown). The anisotropic etch leaves a superlattice trench dielectric sidewall 113 which prevents deposition of silicon or silicon-germanium during the nanosheet region 116 formation process (referred to in FIG. 1AF through 1AI). After the formation of the superlattice trench dielectric sidewall 113, the horizontal surface of the nanosheet superlattice trench 112 is free of dielectric material.

Referring to FIG. 1AF and FIG. 1AG, cross sections are shown after a sacrificial layer 115 and a nanosheet layer 114 form the first layer of the nanosheet region 116. The first layer of the nanosheet region 116 may be formed by epitaxial deposition or atomic-layer deposition (ALD) to produce a layer of a silicon-germanium alloy herein referred to as a sacrificial layer 115. The sacrificial layer 115 may have a thickness in a range between about 10 nm and about 200 nm, though other thicknesses are contemplated. The sacrificial layer 115 is etched away during subsequent processing.

After the deposition of the sacrificial layer 115, a nanosheet dielectric spacer 158 is formed in the sacrificial layer 115 between the source region 132 and the drain region 133 (shown in the top-down view referred to in FIG. 1AA). The formation of the nanosheet dielectric spacer 158 includes of a photolithography step to form a nanosheet dielectric spacer resist pattern, a nanosheet dielectric spacer etch process to remove the sacrificial layer 115 in the exposed region of the nanosheet dielectric resist pattern forming a nanosheet dielectric spacer trench, depositing a dielectric film which fills the nanosheet dielectric spacer trench, followed by a planarization process such as an etch back process to remove the dielectric on the horizontal portion of the sacrificial layer 115 while leaving the nanosheet dielectric in the nanosheet dielectric trench thus forming the nanosheet dielectric spacer 158 (none of the nanosheet dielectric spacer 158 formation processes specifically shown). The nanosheet dielectric spacer 158 may be silicon dioxide, silicon nitride, silicon oxynitride or other similar dielectric materials.

After the formation of the nanosheet dielectric spacer 158, the first nanosheet layer 114 may be formed by epitaxial deposition or ALD on the sacrificial layer 115. The nanosheet layer 114 may have a thickness in a range between about 10 nm and about 200 nm, though other thicknesses are contemplated. The nanosheet layer 114 remains after the sacrificial layer 115 is removed during subsequent processing as a nanosheet layer 114 of the nanosheet transistor 101.

Referring to FIG. 1AH and FIG. 1AI, the process of sacrificial layer 115 formation, nanosheet dielectric spacer 158 formation, and nanosheet layer 114 formation are repeated two more times resulting in a stack consisting of three alternating pairs of sacrificial layers 115 and nanosheet layers 114 with a nanosheet dielectric spacer 158 within each sacrificial layer 115. A nanosheet region 116 with more or fewer nanosheet layers than the example nanosheet transistor 101 is within the scope of the disclosure. After the formation of the nanosheet region 116, the superlattice trench dielectric sidewall 113 is removed.

A drain drift region 117 is formed in the substrate 104, and a portion of the nanosheet region 116, and will subsequently surround the drain region 133 referred to in FIG. 1AT. One or more n-type implants are performed to form the drain drift region 117 (which may be referred to as an n-drift region) in the substrate 104. The n-type dopant that defines the n-drift region 117 may be implanted in one step or in multiple steps. For example, phosphorus may be implanted with a dose such that each of the nanosheet layers 114 receives a dose of about 1×10¹² cm⁻² to about 1×10¹³ cm⁻² with energies suitable for forming the drain drift region 117 with or without subsequent thermal cycles. Arsenic may also be implanted with a similar dose with an energy relatively higher than the phosphorus implant. The drain drift region 117 has an average doping concentration less than the average doping concentration of the drain region 133.

A p-type well region 118 is formed in the substrate 104 and a portion of the nanosheet region 116, and will subsequently surround the source region 132 referred to in FIG. 1AT. One or more p-type implants are performed to form the p-type well region 118 in the substrate 104. The p-type dopant that defines the p-type well region 118 may be implanted in one step or in multiple steps. For example, boron may be implanted at a total dose of between 1×10¹² cm⁻² and 1×10¹³ cm⁻² with energies suitable for forming the p-type well region 118 with or without subsequent thermal cycles. The p-type well region 118 may also receive a heavier implanted dose which does not deplete under reverse bias and is heavy enough to suppress source/drain leakage in the off state. Additionally, the p-type well region 118 doping may be too heavy for use in a p-type nanosheet LDMOS transistor (not specifically shown), if so, p-type drift implant may be required.

Referring to FIG. 1AJ and FIG. 1AK, cross sections are shown after a dielectric layer 119 is deposited. The dielectric layer 119 forms a dielectric gap fill between the nanoshect region 116 and the substrate 104.

Referring to FIG. 1AL and FIG. 1AM, cross sections are shown after a chemical mechanical polish (CMP) process 120 has removed the dielectric layer 119 outside the superlattice sidewall trenches. The dielectric layer 119 acts as a gap fill between the nanosheet region 116 and the substrate 104. After the CMP process 120, the first hard mask layer 109 is removed.

Referring to FIG. 1AN and FIG. 1AO, cross sections are shown after a source/drain trench etch 163 forms a source trench 123 and a drain trench 124. A second pad oxide layer 121 and a second hard mask layer 122 are first formed followed by a source/drain photolithographic pattern 162. After the formation of the source/drain photolithographic pattern 162, a multi-step etch process is used to etch the second hard mask layer 122, the second pad oxide layer 121, and the nanosheet region 116 in the open areas of the source/drain photolithographic pattern 162. After the source trench 123 and the drain trench 124 are formed, a p-body photolithographic pattern is formed (not specifically shown) and an angled implant (not specifically shown) is used to implant p-type dopants in the region down the sides and bottom of the source trench 123, surrounding the source trench 123 to form a p-type body region 125. After the p-type body region 125 is formed, the p-body photolithographic pattern is removed and a n-buffer photolithographic pattern is formed (not specifically shown) and an angled implant (not specifically shown) of a n-type dopant is used to implant n-type dopants along the sides and the bottom of the drain trench 124, in the region surrounding the drain trench 124 to form a n-type buffer region 126. After the formation of the n-type buffer region 126, the n-type buffer photolithographic pattern is removed. Alternatively, plasma doping may be used in some circumstances to implant dopants and form the p-type body region 125 and the n-type buffer region 126.

Referring to FIG. 1AP and FIG. 1AQ, cross sections are shown after an inner spacer dielectric 128 has been deposited by an inner spacer plasma deposition process 129. After the p-type body region 125, and the n-type buffer region 126 are formed, an isotropic SiGe etch, either a plasma etch or a wet etch (not specifically shown) selective to the sacrificial layers 115 is used to remove a portion of the sacrificial layers 115, forming an inner spacer recess 127 near the sidewalls of the p-type body region 125 and the n-type buffer region 126. After the inner spacer recess 127 is formed, a conformal layer of an inner spacer dielectric 128 is formed. The inner spacer dielectric 128 is a conformal dielectric layer which fills the inner spacer recess 127.

Referring to FIG. 1AR and FIG. 1AS, cross sections are shown after an inner spacer dielectric etch 130. The inner spacer dielectric etch 130 is an anisotropic etch which removes the inner spacer dielectric 128 from the top surface of the second hard mask layer 122, and regions inside the source trench 123 and the drain trench 124. The inner spacer dielectric 128 remains in the inner spacer recess 127 regions where a portion of the sacrificial layer 115 of the source trench 123 and the drain trench 124 was previously removed.

Referring to FIG. 1AT and FIG. 1AU cross sections are shown after a polysilicon trench CMP process 131 has completed the formation of a source region 132 and a drain region 133. After the formation of the inner spacer dielectric 128 referred to in FIG. 1AR and 1AS, an n-type polysilicon deposition (not specifically shown) fills the source trench 123 and the drain trench 124 with n-type polysilicon. The n-type silicon deposition to fill the source trench 123 and the drain trench 124 may also be an epitaxial deposition. The polysilicon trench CMP process 131 is used to remove polysilicon outside of source trench 123 and the drain trench 124. After the polysilicon trench CMP process 131, the second hard mask layer 122 and the second pad oxide layer 121 are removed. After the polysilicon CMP process 131 is complete, processes similar to those shown in FIG. 1AN through FIG. 1AU may be repeated using a p-type in-situ polysilicon deposition to form p-type regions such as the p-type back gate region 160 (out of the plane of FIG. 1AT and FIG. 1AU but referred to in FIG. 1AA). The p-type back gate region 160 is later conductively connected to the source region 132 either through a contact and an interconnect, or through a common silicide connection (neither specifically shown).

Referring to FIG. 1AV a cross section is shown after a gate trench 139 is formed. After the formation of the source region 132 and drain region 133 referred to in FIG. 1AN-FIG. 1AU, a third pad oxide 135 and a third hard mask 136 are formed. A gate trench photolithographic mask 137 is patterned on the third hard mask 136. A multi-step gate trench etch 138 removes the third hard mask 136, the third pad oxide 135, and the nanosheet region 116 in regions exposed by the gate trench photolithographic mask 137 forming the gate trench 139. After the formation of the gate trench 139, the gate trench photolithographic mask 137 is removed.

Referring to FIG. 1AW a cross section is shown after a field plate trench 159 is formed. After the formation of the gate trench 139, a field plate trench photolithographic mask 165 is patterned on the third hard mask 136. A multi-step field plate trench etch 166 removes the third hard mask 136, the third pad oxide 135, and the nanosheet region 116 in regions exposed by the field plate trench photolithographic mask 165 forming the field plate trench 159. After the formation of the field plate trench 159, the field plate trench photolithographic mask 165, the third hard mask 136, and the third pad oxide 135 are removed.

Referring to FIG. 1AX and FIG. 1AY cross sections are shown after a plasma etch or a wet etch process which selectively removes the sacrificial layers 115 of the nanosheet region 116 between the source region 132 and the drain region 133, leaving superlattice voids 140 with adjacent nanosheet layers 114 remaining. The superlattice voids 140 leave the nanosheet layers 114 suspended over the substrate 104 by attachments to the source region 132 and the drain region 133. After removing the sacrificial layers 115 a cleanup process that includes supercritical CO₂ may be employed to remove residues.

Referring to FIG. 1AZ, FIG. 1BA and FIG. 1BB, cross sections are shown after an oxidation process and polysilicon deposition process (sometimes not specifically shown) form a dielectric layer 141 herein referred to as a nanosheet dielectric layer 141 touching the nanosheet layers 114, the gate conductor 142 touching the nanosheet dielectric layer 141, and the field plate conductor 157 also touching the nanosheet dielectric layer 141. The nanosheet dielectric layer 141 may be silicon dioxide based, nitrided silicon dioxide based, metal gate based, or other appropriate dielectric material used in semiconductor applications. In the examples shown in FIG. 1AZ, FIG. 1BA and FIG. 1BB, a single polysilicon deposition is used to form the gate conductor 142 and the field plate conductor 157, but are labeled as the gate conductor 142 and the field plate conductor 157 as they will become electrically isolated from each other during later processing. The nanosheet dielectric spacer 158 provides electrical isolation between the gate conductor 142 and the field plate conductor 157 between the nanosheet layers 114. Isolation of the polysilicon on the top surface 107 of the nanoshect transistor 101 between the gate conductor 142 and the field plate conductor 157 is accomplished through a polysilicon etch process referred to in FIG. 1BG. The nanosheet dielectric layer 141 may be formed by thermal oxidation of the nanosheet layers 114, forming a continuous sheath around cach of the nanosheet layers 114 between the source region 132 and the drain region 133. The polysilicon deposition fills the superlattice voids 140, the gate trenches 139, the field plate trenches 159, and forms a continuous layer over the nanosheet region 116.

Referring to FIG. 1BC and FIG. 1BD, cross sections are shown after an isolation trench etch 145 has formed an isolation trench 146. To form the isolation trench 146, a fourth hard mask 143 is formed on the gate conductor 142 and the field plate conductor 157. After formation of the fourth hard mask 143, an isolation trench photomask 144 is formed. The isolation trench etch 145 forms the isolation trench 146 in the open areas of the isolation trench photomask 144 by etching portions of the fourth hard mask 143, the gate conductor 142, the field plate conductor 157, the nanosheet dielectric layer 141, the source region 132, the drain region 133, and the nanosheet region 116. The isolation trench etch 145 also etches into, and stops in the semiconductor material 103. After the isolation trench etch 145, the isolation trench photomask 144 is removed. The fourth hard mask 143 remains in place as an etch stop for a subsequent STI CMP process 147 referred to in FIG. 1BE and FIG. 1BF.

Referring to FIG. 1BE and FIG. 1BF, cross sections are shown after the STI CMP process 147 has formed a shallow a STI region 148. The STI region 148 is formed by first forming a layer of a silicon dioxide or similar dielectric in the isolation trench 146 and on the fourth hard mask 143 (referred to in FIG. 1BC and FIG. 1BD) of the nanosheet transistor 101. A high-density plasma (HDP) deposition or a high aspect ratio plasma (HARP) technique may be used to fill the isolation trench 146 by way of example. The STI CMP process 147 may be used to remove the dielectric overburden outside the isolation trench 146, leaving an STI region 148 in the isolation trench 146. The STI region 148 isolates the nanosheet layers 114, the source region 132, and the drain region 133 from the nanosheet region 116 remaining between the STI region 148 and the dielectric layer 119. After the STI CMP process 147, the fourth hard mask 143 referred to in FIG. 1BC and FIG. 1BD (not specifically shown in FIG. 1BE and FIG. 1BF), is removed using a phosphoric acid chemistry, and a HF based chemistry is used to achieve the specified final profile of the STI region 148.

Referring to FIG. 1BG and FIG. 1BH, cross sections are shown after a gate and field plate conductor plasma etch 150. A gate and field plate conductor photomask 149 is formed on the gate conductor 142 and the field plate conductor 157. After the formation of the gate and field plate conductor photomask 149, a gate and field plate conductor plasma etch 150 removes the gate conductor 142, the field plate conductor 157, and the nanosheet dielectric layer 141 in the open areas of the gate and field plate conductor photomask 149 providing electrical isolation between the gate conductor 142 and the field plate conductor 157 at the top surface 107 of the nanosheet transistor 101. The nanosheet dielectric spacer 158 provides electrical isolation between the gate conductor 142 and the field plate conductor 157 in the regions between the nanosheet layers 114. After the gate and field plate conductor plasma etch 150, the gate and field plate conductor photomask 149 is removed.

After the gate and field plate conductor photomask 149 is removed, sidewall spacers (not specifically shown) may be formed on the vertical surfaces of the gate conductor 142 and the field plate conductor 157, and may extend 50 nm to 200 nm from the lateral edges of the gate conductor 142 and the field plate conductor 157. The sidewall spacers may prevent subsequent silicide formation on the vertical surfaces of the gate conductor 142, the field plate conductor 157, and silicon containing areas under the sidewall spacers.

FIG. 1BI and FIG. 1BJ, shows cross sections of the nanosheet transistor 101 after the formation of a first level of interconnects 156. A metal silicide layer (not specifically shown) may be formed on the source region 132, the drain region 133, the p-type back gate region 160 (out of the plane of the cross sections shown in FIG. 1BI and FIG. 1BJ, referred to in FIG. 1AA) and exposed portions of the gate conductor 142 and the field plate conductor 157. The metal silicide layer may provide ohmic electrical connections to the source region 132, the drain region 133, the p-type back gate region 160, the gate conductor 142, and the field plate conductor 157 with lower resistances compared to a similar microelectronic device without metal silicide layer.

A pre-metal dielectric (PMD) layer 151 is formed over the top surface 107 of the substrate 104. The PMD layer 151 may include one or more dielectric layers, such as silicon nitride, silicon oxynitride, and silicon dioxide. In some examples, the PMD layer 151 includes a PMD liner and a main dielectric sublayer formed on the PMD liner. Subsequently, the PMD layer 151 may be planarized by a CMP process (not specifically shown). A source contact 152, a gate contact 154, a field plate contact 155, and a drain contact 153 may be formed in the PMD layer 151 using tungsten plugs or other suitable methods to form an electrical connection to an interconnects 156. The interconnects 156 are formed over the PMD layer 151 using any suitable metallization scheme and provide electrical contact between the nanosheet transistor 101 and other components of the microelectronic device 100.

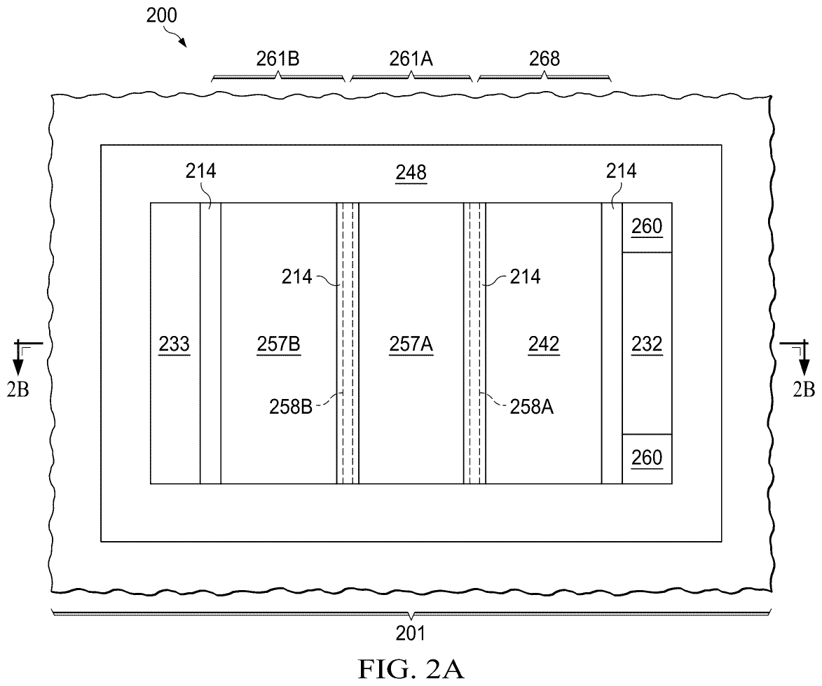

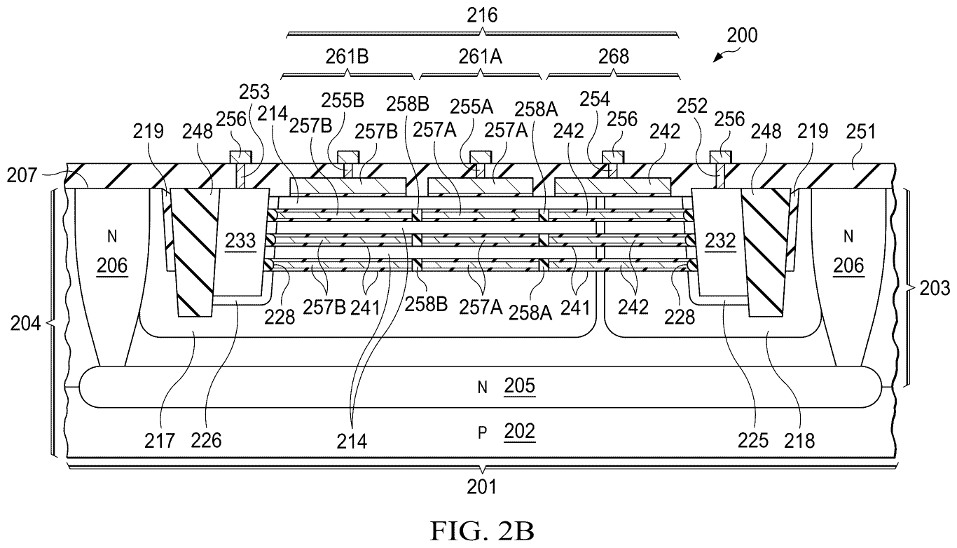

FIG. 2A is a top-down representation of a microelectronic device 200 including a nanosheet transistor 201 which contains multiple field plates, in this case a first field plate conductor 257A in a first field plate region 261A, a second field plate conductor 257B in a second field plate region 261B as well as a gate conductor 242 in a gate region 268. More than one field plate may be used in the off state to distribute the source region 232 potential drop into smaller drops which may add in a more gradual monotonic voltage drop from the drain region 233 to the source region 232 and hence more ideal, enabling a shorter drift region for a given breakdown voltage. The general formation process for the nanosheet transistor 201 is similar to the nanosheet transistor 101 referred to in FIG. 1AA-FIG. 1BJ. The nanosheet transistor 201 contains a source region 232, a drain region 233, and a back gate region 260. Unlike the nanosheet transistor 101 referred to in FIG. 1AA, the nanosheet transistor 201 contains a first nanosheet dielectric spacer 258A, the first field plate conductor 257A, a second nanosheet dielectric spacer 258B and the second field plate conductor 257B. While the example microelectronic device 200 contains a first nanosheet dielectric spacer 258A, a second nanosheet dielectric spacer 258B, a first field plate conductor 257A, and a second field plate conductor 257B, a nanosheet transistor 201 with additional dielectric spacers and field plates is within the scope of the disclosure. Additional elements of FIG. 2A include an STI isolation region 248, and portions of the nanosheet layer 214 that are visible in a top-down view.

FIG. 2B is a cross section of a nanoshect transistor 201 shown in FIG. 2A containing a first nanosheet dielectric spacer 258A, a second nanosheet dielectric spacer 258B, the first field plate region 261A, and the second field plate region 261B. The nanosheet transistor 201 contains a nanosheet region 216 of nanosheet layers 214 between a source region 232 and a drain region 233. A nanosheet dielectric layer 241 is around the nanosheet layers 214 and provides electrical isolation between the gate conductor 242 and the nanoshect layers 214 as well as electrical isolation between the first field plate conductor 257A, the second field plate conductor 257B and the nanosheet layers 214. A first nanosheet dielectric spacer 258A and a second nanosheet dielectric spacer 258B are between the source region 232 and the drain region and between nanosheet layers 214 which are vertically adjacent to each other. A gate conductor 242, which is between the source region 232 and the first nanosheet dielectric spacer 258A is in the gate region 268. A first field plate conductor 257A is between the first nanosheet dielectric spacer 258A and the second nanosheet dielectric spacer 258B in the first field plate region 261A. A second field plate conductor 257B is between the second nanosheet dielectric spacer 258B and the drain region 233 in the second field plate region 261B.

Other elements of the nanoshect transistor 201 include a base wafer 202, a silicon layer 203, a substrate 204, an n-type buried layer 205, a deep well 206, a top surface 207 of the substrate 204, a n-type drift region 217, a p-type well region, 218, a superlattice trench fill 219, a p-type body 225, a n-type buffer 226, an inner spacer dielectric 228, the isolation region 248, a pre-metal dielectric 251, a source contact 252, a drain contact 253, a gate contact 254, a first field plate contact 255A, a second field plate contact 255B, and metallization 256.

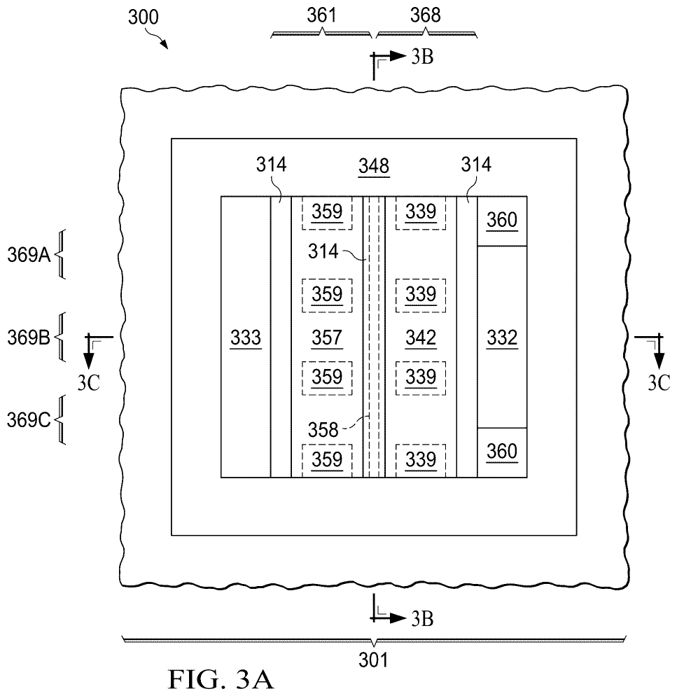

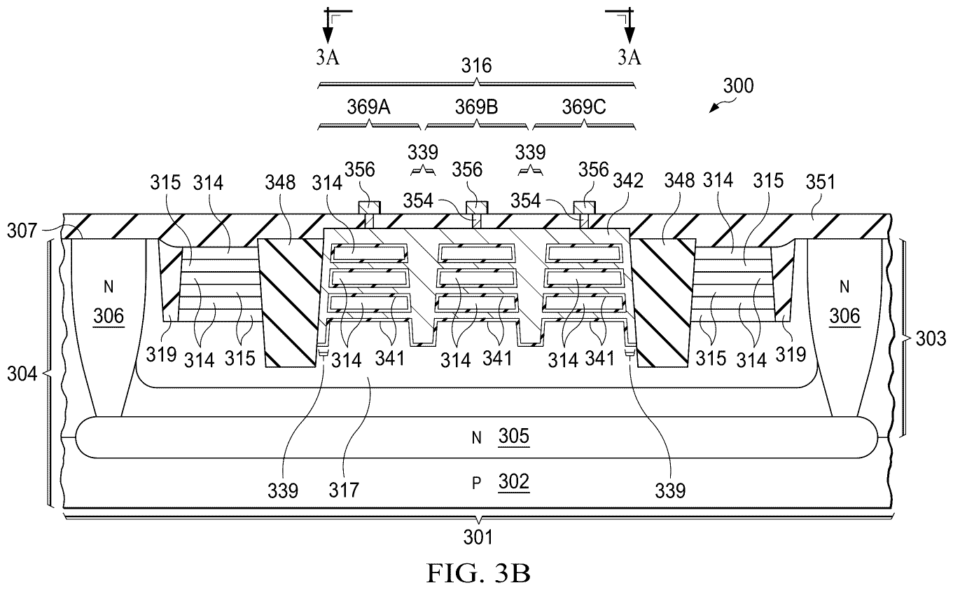

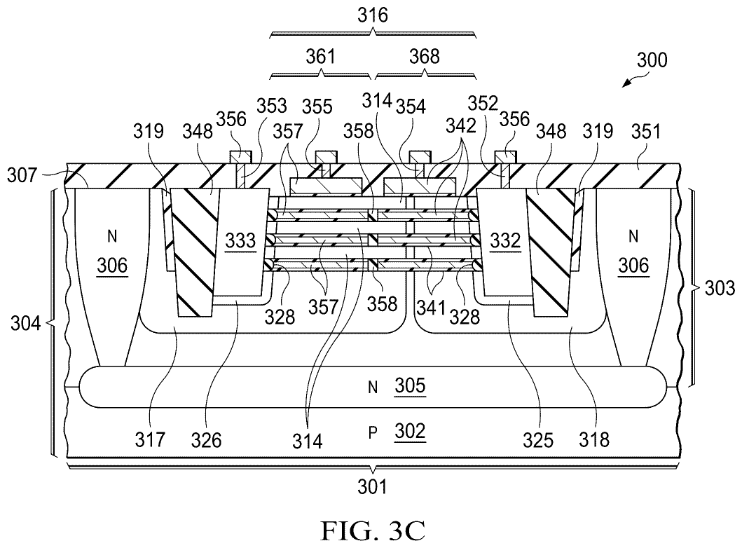

FIG. 3A is a top-down representation of a microelectronic device 300 including a nanosheet transistor 301 with multiple nanosheet transistor fingers. While the example nanosheet transistor 301 has three nanosheet transistor fingers in a first nanosheet transistor finger 369A, a second nanosheet transistor finger 369B and a third nanosheet transistor finger 369C, a nanosheet transistor 301 with fewer or more than three nanosheet transistor fingers is within the scope of the disclosure. The general formation process for the nanosheet transistor 301 is similar to the nanoshect transistor 101 referred to in FIG. 1AA-FIG. 1BJ. The nanoshect transistor contains a source region 332, a drain region 333, a back gate region 360, a gate region 368, a field plate region 361, and a nanoshect dielectric spacer 358 between the gate region 368 and the field plate region 361. Unlike the nanoshect transistor 101 referred to in FIG. 1AA, the nanoshect transistor 301 contains a plurality of gate trenches 339 and field plate trenches 359 between the source region 332 and the drain region 333, such that a nanosheet transistor fingers (369A, 369B, or 369C) contacting the source region 332 and the drain region 333 are each between a pair of gate trenches 339 in the gate region 368 and a pair of field plate trenches 359 in the field plate region 361. Additional elements of FIG. 3A include a STI isolation region 348, and portions of the nanosheet layer 314 that are visible in a top-down view.

FIG. 3B is a cross section of a microelectronic device 300 containing a nanosheet transistor 301 of FIG. 3A showing the plurality of gate trenches 339 as well as the three nanosheet transistor fingers (369A, 369B, and 369C). The gate trenches 339 extend from the top surface 307 to a point below the nanosheet layers 314 in the p-type well region 318. The nanosheet layers 314 of cach finger (369A, 369B, and 369C) arc surrounded by a nanosheet dielectric layer 341 which is on the nanosheet layers 314, and a gate conductor 342 is on the nanosheet dielectric layer 341. The gate conductor 342 fills the space between all of the nanosheet layers 314 as well as the gate trenches 339 between the nanosheet layers 314. The nanosheet dielectric spacer 358 is out of the plane of the cross-sectional view shown in FIG. 3B.

Additional elements of the nanosheet transistor 301 include a base wafer 302, a silicon layer 303, a substrate 304, an n-type buried layer 305, a deep well 306, unremoved areas of the original silicon-germanium layer 315 which are outside of the STI isolation region 348, a superlattice trench fill 319, a pre-metal dielectric 351, a gate contact 354, and metallization 356.

FIG. 3C is a cross section of a microelectronic device 300 shown in FIG. 3A with a nanosheet transistor 301 containing a nanosheet dielectric spacer 358 and multiple nanosheet transistor fingers, the cross section of FIG. 3C being along the plane between the source region 332, the drain region 333 and the second nanosheet transistor finger 369B. The nanosheet transistor 301 contains a nanosheet region 316 of the nanosheet layers 314 between a source region 332 and a drain region 333. A nanosheet dielectric layer 341 is around the nanosheet layers 314 and provides electrical isolation between the gate conductor 342 and the nanosheet layers 314 as well as electrical isolation between the field plate conductor 357 and the nanosheet layers 314. The nanosheet dielectric spacers 358 are between the field plate region 361 and the gate region 368 between the nanosheet layers 314 and are vertically adjacent to each other. The gate conductor 342, is on the nanosheet dielectric layer 341 between the source region 332 and the nanoshect dielectric spacers 358, and fills the voids between the nanosheet layers 314 as well as an area on the top surface 307 of the nanosheet transistor 301 in the gate region 368. A field plate conductor 357 is on the nanosheet dielectric layer 341 between the nanosheet dielectric spacers 358 and the drain region 333 and fills the voids between the nanosheet layers 314 as well as an area on the top surface 307 of the nanosheet transistor 301 in the field plate region 361.

Other elements of the nanosheet transistor 301 include a base wafer 302, a silicon layer 303, a substrate 304, an n-type buried layer 305, a deep well 306, a top surface 307 of the substrate 304, a n-type drift region 317, a p-type well region 318, a superlattice trench fill 319, a p-type body 325, a n-type buffer 326, an inner spacer dielectric 328, a STI isolation region 348, a pre-metal dielectric 351, a source contact 352, a drain contact 353, a gate contact 354, a field plate contact 355 and metallization 356.

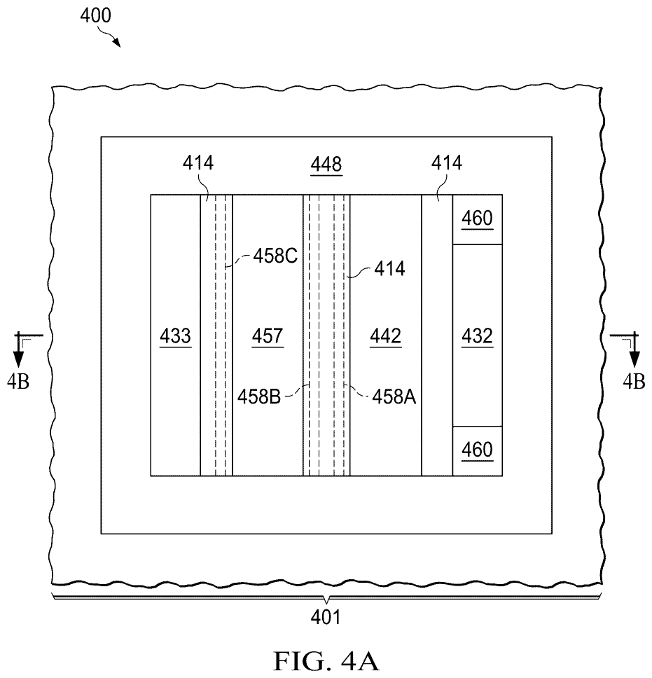

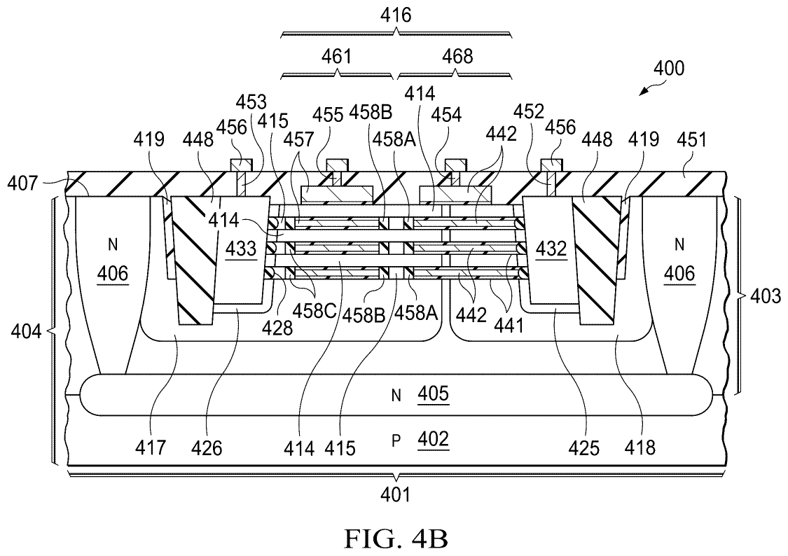

FIG. 4A is a top-down representation of a microelectronic device 400 including a nanosheet transistor 401 containing a first nanosheet dielectric spacer 458A, a second nanosheet dielectric spacer 458B, and a third nanosheet dielectric spacer 458C, between the source region 432 and the drain region 433. Multiple dielectric spacers or larger dielectric spacers may allow smaller field plates regions 461 to be used for a given field plate pitch along a drain drift region 417. This may reduce the electric field stress between a field plate conductor 457 and the nanosheet layer 414 it surrounds as the potential will be dropping monotonically in the nanosheet layer 414 in the off state, whereas a field plate conductor 457 is made of the same material as a gate conductor 442 so it is at a single potential. Therefore, regions of higher field can occur between the field plate conductor 457 corner and the nanosheet layer 414 nearest to it.

The general formation process for the nanosheet transistor 401 is similar to the formation of the nanosheet transistor 101 referred to in FIG. 1AA-FIG. 1BJ. The nanosheet transistor 401 contains a source region 432, a drain region 433, and a back gate region 460. While the example microelectronic device 400 contains three nanosheet dielectric spacers 458A, 458B, and 458C, a nanosheet transistor 401 with fewer or additional nanosheet dielectric spacers is within the scope of the disclosure. Additional elements of FIG. 4A include a STI isolation 448, portions of a nanosheet layer 414, the field plate conductor 457 in a field plate region 461 and the gate conductor 442 in the gate region 468.

FIG. 4B is a cross section of a nanosheet transistor 401 containing three nanosheet dielectric spacers 458A, 458B, and 458C. The nanosheet transistor 401 contains a nanosheet region 416 of nanosheet layers 414 between a source region 432 and a drain region 433. A nanosheet dielectric layer 441 is around the nanoshect layers 414 and provides electrical isolation between the gate conductor 442 and the nanosheet layer 414 as well as electrical isolation between the field plate conductor 457, and the nanosheet layers 414. Between the nanosheet layers 414, the first nanosheet dielectric spacer 458A and the second nanosheet dielectric spacer 458B are between the gate region 468 and the field plate region 461 and the third nanosheet dielectric spacer 458C is between the field plate region 461 and the drain region 433. The gate conductor 442, which is between the source region 432 and the first nanosheet dielectric spacer 458A is on the nanosheet dielectric layer 441. The field plate conductor 457 is between the second nanosheet dielectric spacer 458B and the third nanosheet dielectric spacer 458C and is on the nanosheet dielectric layer 441. A region of the sacrificial layers 415 remains between the third nanosheet dielectric spacer 458C and an inner spacer dielectric 428 as well as between the first nanosheet dielectric spacer 458A and the second nanosheet dielectric spacer 458B as these regions were not in contact with the field plate trench 159 or gate trench 139 referred to in FIG. 1AV through FIG. 1AY, and thus the sacrificial layers 415 were not removed. The gate region 468 and the field plate region 461 are electrically isolated from each other by the first nanosheet dielectric spacer 458A and the second nanosheet dielectric spacer 458B.

Other elements of the nanosheet transistor 401 include a base wafer 402, a silicon layer 403, a substrate 404, an n-type buried layer 405, a deep well 406, a top surface 407 of the substrate, a drain drift region 417, a p-type well region, 418, a superlattice trench fill 419, a p-type body 425, a n-type buffer 426, an inner spacer dielectric 428, STI isolation 448, a pre-metal dielectric 451, a source contact 452, a drain contact 453, a gate contact 454, a field plate contact 455, and metallization 456.

While various examples of the present disclosure have been described above, it should be understood that they have been presented by way of example and not limitation. As such, although foregoing examples are described to use various resist layers (e.g., Photoresist or photomask layers) to perform various process steps (e.g., Implant steps or etch steps), the present disclosure is not limited thereto. For example, one or more hard masks (including one or more layers) may be patterned to define various regions for subsequent process steps to be applied (e.g., Regions for receiving dopant atoms, regions to block etchants). Moreover, the resist layers may include multi-level resists instead of a single-level resist in some examples. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the following claims and equivalents.

What is claimed is:

1. A microelectronic device, comprising:
a first doped semiconductor region and a second doped semiconductor region extending into a semiconductor substrate, the first and second doped semiconductor regions having a first conductivity type and the semiconductor substrate having an opposite second conductivity type;
a semiconductor layer contacting the first doped semiconductor region and the second doped semiconductor region;
a first conductive layer extending between the first doped semiconductor region and the second doped semiconductor region;
a second conductive layer extending between the second doped semiconductor region and the first conductive layer; and
a dielectric layer touching the semiconductor layer, the first conductive layer and the second conductive layer.

2. The microelectronic device as recited in claim 1, further comprising a dielectric spacer between and touching the first and second conductive layers.

3. The microelectronic device as recited in claim 2, wherein the semiconductor layer is one of first and second semiconductor layers connected between the first doped semiconductor region and the second doped semiconductor region, and the first and second conductive layers, the dielectric layer, and the dielectric spacer being between the first and second semiconductor layers.

4. The microelectronic device as recited in claim 1, wherein the first doped semiconductor region is a source region and the second doped semiconductor region is a drain region, the source region and the drain region having a first average dopant concentration, and further comprising a drain drift region having the first conductivity type and a lower second dopant concentration in the semiconductor layer and extending from the drain region toward the source region, and a channel region having the second conductivity type between the drain drift region and the source region.

5. The microelectronic device as recited in claim 4, further comprising a well region having the second conductivity type within the semiconductor layer and the semiconductor substrate, surrounding the source region, and extending from the source region towards the drain region.

6. The microelectronic device as recited in claim 4, wherein the source region extends into a trench within the semiconductor substrate and further comprising a body region having the second conductivity type along sides and a bottom of the trench.

7. The microelectronic device as recited in claim 4, wherein the drain region extends into a trench within the semiconductor substrate and further comprising a buffer region having the first conductivity type along sides and a bottom of the trench.

8. The microelectronic device as recited in claim 1, further comprising a gate trench extending into the semiconductor substrate, the gate trench filled by the first conductive layer.

9. The microelectronic device as recited in claim 1, further comprising a field plate trench extending into the semiconductor substrate, the field plate trench filled by the second conductive layer.

10. The microelectronic device as recited in claim 3, further comprising an inner spacer of a dielectric material contacting a source region between the first and second semiconductor layers electrically isolating the first conductive layer from the source region, and an inner spacer of a dielectric material contacting a drain region between the first and second semiconductor layers, electrically isolating second conductive layer from the drain region.

11. The microelectronic device recited in claim 1, wherein the semiconductor layer has a thickness greater than 10 nm.

12. A method of forming a microelectronic device, comprising:
forming a trench in a semiconductor substrate having a first conductivity type;
forming a semiconductor nanosheet stack in the trench, including a semiconductor layer and a sacrificial layer;
forming a source region and a drain region having an opposite second conductivity type extending into the semiconductor nanosheet stack;
removing the sacrificial layer between the source region and the drain region;
forming a dielectric spacer contacting the semiconductor layer between the source region and the drain region;
forming a dielectric layer on the semiconductor layer;
forming a first conductive layer on the dielectric layer between the source region and the dielectric spacer; and
forming a second conductive layer on the dielectric layer between the drain region and the dielectric spacer.

13. The method of claim 12, wherein forming the semiconductor nanosheet stack includes forming first and second semiconductor layers, the sacrificial layer being between the first and second semiconductor layers.

14. The method of claim 13, wherein forming the source region and the drain region includes forming a source trench and a drain trench extending into the semiconductor nanosheet stack, and further comprising forming recesses in the sacrificial layer at sidewalls of the source trench and the drain trench, and filling the recesses with an inner spacer, the inner spacer electrically isolating the first conductive layer from the source region and the second conductive layer from the drain region.

15. The method of claim 13, wherein forming the drain region includes forming a drain trench extending into the semiconductor nanosheet stack, and further comprising forming a buffer region of the second conductivity type along a sidewall of the drain trench.

16. The method of claim 13, further comprising forming a drift region of the second conductivity type in the semiconductor nanosheet stack and the semiconductor substrate, the drift region extending from the drain region toward the source region.

17. The method of claim 13, further comprising forming a body region of the first conductivity type in the semiconductor nanosheet stack, the body region extending from the source region toward the drain region.

18. The method of claim 13, further comprising forming a well region of the first conductivity type in the semiconductor nanosheet stack and the semiconductor substrate, the well region surrounding a body region and the source region.

19. The method of claim 13, further comprising forming a first gate trench and a second gate trench extending through the semiconductor nanosheet stack, the first conductive layer extending from the first gate trench to the second gate trench.

20. The method of claim 13, further comprising forming a first field plate trench and a second field plate trench extending through the semiconductor nanosheet stack, the second conductive layer extending from the first field plate trench to the second field plate trench.
